(19) United States
(12) Patent Application Publication
(10) Pub. No.: US 2025/0029852 A1
(43) Pub. Date: Jan. 23, 2025

(54) SUBSTRATE PROCESSING METHOD AND SUBSTRATE PROCESSING SYSTEM

(71) Applicant: Tokyo Electron Limited, Tokyo (JP)

(72) Inventor: Hiroshi MARUMOTO, Koshi City, Kumamoto (JP)

(21) Appl. No.: 18/716,150

(22) PCT Filed: Nov. 22, 2022
(86) PCT No.: PCT/JP2022/043160

§ 371 Date: Jun. 4, 2024

(30) Foreign Application Priority Data
Dec. 6, 2021 (JP) 2021-198045

(51) Int. Cl. H01L 21/67; H01L 21/66

(52) U.S. Cl. CPC H01L 21/67253; H01L 21/6708; H01L 22/26

(57) ABSTRACT

Predicting of an etching amount distribution in a diametrical direction of an etching target includes: acquiring learning data including etching amount distribution when a surface of the etching target is etched under multiple different etching conditions; and predicting the etching amount distribution under prediction target etching conditions from following equations (1) to (6) by using the learning data.

$${ER}_{scan} ( R ) = {ER}_{ref} ( R ) \times {Ratio}_{scan} ( R ) \qquad ( 1 )$$

$${Ratio}_{scan} ( R ) = {b}_{0} \times exp ( {b}_{1} \times T + {b}_{2} ) + C \qquad ( 2 )$$

$${b}_{0} = f ( S , V ) \qquad ( 3 )$$

$${b}_{1} = f ( S , V ) \qquad ( 4 )$$

$${b}_{2} = f ( S , V ) \qquad ( 5 )$$

$$T = ( L - R ) / V \qquad ( 6 )$$

### TECHNICAL FIELD

The various aspects and embodiments described herein pertain generally to a substrate processing method and a substrate processing system.

### BACKGROUND

Patent Document 1 describes a substrate processing method including a grinding process of grinding a surface of a substrate, a measuring process of measuring a thickness of the ground substrate, a condition determining process of determining processing conditions for a wet etching to be performed on the substrate based on the measured thickness of the substrate, and an etching process of performing the wet etching by supplying a processing liquid to the ground substrate under the determined processing conditions.

### PRIOR ART DOCUMENT

Patent Document 1: Japanese Patent Laid-open Publication No. 2018-147908

### DISCLOSURE OF THE INVENTION

### Problems to be Solved by the Invention

Exemplary embodiments provide a technique capable of appropriately predicting an etching amount distribution of an etching target in a diametrical direction when etching a surface of the etching target while rotating the etching target and reciprocating an etching liquid supply in the diametrical direction.

### Means for Solving the Problems

In an exemplary embodiment, a substrate processing method of processing a substrate includes etching a surface of an etching target on the substrate by supplying an etching liquid from an etching liquid supply to the surface, while rotating the etching target and reciprocating the etching liquid supply in a diametrical direction through a position above a rotation center of the etching target; and predicting an etching amount distribution in the diametrical direction of the etching target when etching the surface of the etching target under prediction target etching condition. The predicting of the etching amount distribution includes: acquiring learning data including etching amount distribution when the surface of the etching target is etched under multiple different etching conditions; and predicting the etching amount distribution under the prediction target etching conditions from following equations (1) to (6) by using the learning data.

$${ER}_{scan} ( R ) = {ER}_{ref} ( R ) \times {Ratio}_{scan} ( R ) \qquad ( 1 )$$

$${Ratio}_{scan} ( R ) = {b}_{0} \times exp ( {b}_{1} \times T + {b}_{2} ) + C \qquad ( 2 )$$

$${b}_{0} = f ( S , V ) \qquad ( 3 )$$

$${b}_{1} = f ( S , V ) \qquad ( 4 )$$

$${b}_{2} = f ( S , V ) \qquad ( 5 )$$

$$T = ( L - R ) / V \qquad ( 6 )$$

ER_{scan}: Etching amount when the etching liquid supply is reciprocated
ER_{ref}: Etching amount when the etching liquid supply is not reciprocated
Ratio_{scan}: Scan ratio
R: Position from the center of the etching target
T: Non-discharge time during which the etching liquid is not supplied
C: Constant
S: Rotation speed when rotating the etching target
V: Scan speed when reciprocating the etching liquid supply
L: Scan width when reciprocating the etching liquid supply

### Effect of the Invention

According to the exemplary embodiment, it is possible to appropriately predict the etching amount distribution of the etching target in the diametrical direction when etching the surface of the etching target while rotating the etching target and reciprocating the etching liquid supply in the diametrical direction.

### BRIEF DESCRIPTION OF THE DRAWINGS

FIG. 1 is a side view illustrating an example of a combined wafer to be processed in a wafer processing system.

FIG. 2 is a plan view schematically illustrating a configuration of the wafer processing system.

FIG. 3 is a side view illustrating a schematic configuration of an etching apparatus.

FIG. 4 is an explanatory diagram illustrating a state in which an etching liquid supply is being moved in a diametrical direction.

FIG. 5 is an explanatory diagram showing a constant speed scan sequence.

FIG. 6 is an explanatory diagram illustrating examples of learning data.

FIG. 7 is an explanatory diagram showing the examples of the learning data and a reference etching amount distribution.

FIG. 8 is an explanatory diagram showing a scan ratio distribution in the diametrical direction.

FIG. 9 is an explanatory diagram showing a non-discharge time distribution in the diametrical direction.

FIG. 10 is an explanatory diagram showing a relationship between the scan ratio and the non-discharge time.

FIG. 11 is an explanatory diagram providing comparison of an actual measurement value of the etching amount distribution of the constant speed scan sequence and a calculation value of an etching amount distribution of a constant speed scan model.

FIG. 12 is a flowchart illustrating main processes of a wafer processing.

FIG. 13 is a flowchart illustrating main processes of an optimal etching condition determining method.

FIG. 14 is an explanatory diagram illustrating a plurality of connection sequences.

FIG. 15 is an explanatory diagram illustrating etching amount distributions of the constant speed scan sequence and the plurality of connection sequences.

FIG. 16 is an explanatory diagram illustrating an asymmetric scan sequence.

FIG. 17 is an explanatory diagram illustrating etching amount distributions of the constant speed scan sequence and the asymmetric scan sequence.

FIG. 18 is an explanatory diagram illustrating a variable speed scan sequence.

FIG. 19 is an explanatory diagram showing a change in the position of an etching liquid supply over time in the variable speed scan sequence.

FIG. 20 is an explanatory diagram illustrating a range from a center to a shifting point in FIG. 19.

FIG. 21 is an explanatory diagram illustrating a range from the shifting point to a scan end in FIG. 19.

FIG. 22 is an explanatory diagram showing an actual measurement value and a calculation value of an etching amount distribution of the variable speed scan sequence.

FIG. 23 is an explanatory diagram showing an actual measurement value and a calculation value of an etching amount distribution of the variable speed scan sequence.

### DETAILED DESCRIPTION

In a semiconductor device manufacturing process, a semiconductor substrate (hereinafter referred to as “wafer”) having a plurality of devices such as electronic circuits formed on a surface thereof is ground to be thinned, and the ground surface of the wafer is smoothed. The smoothing of the ground surface is carried out through, for example, so-called spin etching in which an etching liquid is supplied from above the ground surface of the wafer while the wafer is being rotated.

It is described in the aforementioned Patent Document 1 that a damage layer formed on the surface of the wafer due to the grinding processing is removed by performing the wet etching processing on the wafer after being subjected to the grinding processing. In the condition determining process described in Patent Document 1, an operation of a nozzle configured to supply the processing liquid, a rotation speed of the wafer, a supply amount of the processing liquid, a supply time of the processing liquid, a kind of the processing liquid, and so forth are determined as conditions for the wet etching processing, based on the thickness of the wafer obtained in the measuring process.

However, when performing the spin etching by supplying the processing liquid while rotating the wafer as in the method disclosed in Patent Document 1, the processing liquid supplied to the surface of the wafer flows diametrically outwards due to a centrifugal force, making it difficult to perform a precise etching control. More specifically, it has been difficult to properly control a surface shape of the wafer after being etched, especially at a central portion of the wafer.

In this regard, it has been proposed to etch the surface of the wafer by supplying an etching liquid to the surface of the wafer from a nozzle while rotating the wafer and reciprocating (scanning) the nozzle in a diametrical direction to pass through a center of the wafer. Hereinafter, such etching may be referred to as “scan etching”. In this scan etching, the surface shape of the wafer is controlled by supplying the etching liquid to the central portion of the wafer while generating a flow of the etching liquid on the surface of the wafer at the central portion.

Here, in order to control the surface shape of the wafer after being etched, it becomes very important to appropriately control an etching amount distribution (etching profile) in the diametrical direction of the wafer. The etching amount distribution is controlled by adjusting etching conditions (etching recipe) such as a rotation speed (rpm) of the wafer, a scan speed in reciprocating movements of the nozzle, a scan width, and so forth, to thereby acquire a target etching amount distribution.

Conventionally, however, a so-called trial-and-error method in which an engineer predicts a variation in the etching amount distribution, acquires data on the etching amount distribution sequentially, and adjusts the etching amount distribution to a target has been a mainstream practice in controlling the etching amount distribution. In such a case, however, the control of the etching amount distribution depends on the ability of the engineer, and there may be caused individual differences in working time required for the control and in the degree of completeness of the control.

In view of the foregoing, exemplary embodiments provide a technique capable of appropriately predicting an etching amount distribution of an etching target in a diametrical direction in scan etching. Hereinafter, a wafer processing system and a wafer processing method according to an exemplary embodiment will be described with reference to the accompanying drawings. In the present specification and the drawings, parts having substantially the same functions and configurations will be assigned same reference numerals, and redundant description thereof will be omitted.

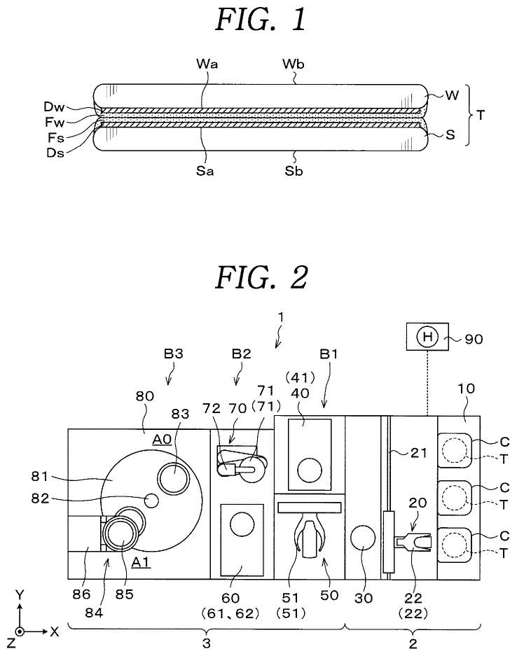

In a wafer processing system 1 to be described later according to an exemplary embodiment, a processing is performed on a combined wafer T as a substrate in which a first wafer W and a second wafer S are bonded to each other as shown in FIG. 1. Hereinafter, in the first wafer W, a surface to be bonded to the second wafer S is referred to as a front surface Wa, and a surface opposite to the front surface Wa is referred to as a rear surface Wb. Likewise, in the second wafer S, a surface to be bonded to the first wafer W is referred to as a front surface Sa, and a surface opposite to the front surface Sa is referred to as a rear surface Sb.

The first wafer W is, for example, a semiconductor wafer such as a silicon substrate, and a device layer Dw including a plurality of devices is formed on the front surface Wa of the first wafer W. Further, a bonding film Fw is further formed on the device layer Dw, and the first wafer W is bonded to the second wafer S with the bonding film Fw therebetween. An oxide film (a THOX film, a SiO₂ film, a TEOS film), a SiC film, a SiCN film, or an adhesive is used as an example of the bonding film Fw.

The second wafer S has the same structure as the first wafer W, for example, and a device layer Ds and a bonding film Fs are formed on the front surface Sa of the second wafer S. However, the second wafer S does not need to be a device wafer on which the device layer Ds is formed, and it may be, for example, a support wafer that supports the first wafer W. In this case, the second wafer S functions as a protective member that protects the device layer Dw of the first wafer W.

As illustrated in FIG. 2, the wafer processing system 1 has a configuration in which a carry-in/out station 2 and a processing station 3 are connected as one body. In the carry-in/out station 2, a cassette C capable of accommodating therein a plurality of combined wafers T is carried to/from the outside, for example. The processing station 3 is equipped with various types of processing apparatuses configured to perform required processings on the combined wafer T.

The carry-in/out station 2 is equipped with a cassette placing table 10 on which a plurality of, e.g., three cassettes C are placed thereon. Further, a wafer transfer device 20 is provided adjacent to the cassette placing table 10 on the negative X-axis side of the cassette placing table 10. The wafer transfer device 20 is configured to be movable on a transfer path 21 extending in the Y-axis direction. Further, the wafer transfer device 20 has, for example, two transfer arms 22 each configured to hold and transfer the combined wafer T. Each transfer arm 22 is configured to be movable in a horizontal direction and a vertical direction and pivotable around a horizontal axis and a vertical axis. Furthermore, the configuration of the transfer arm 22 is not limited to that of the present exemplary embodiment, and the transfer arm 22 may have any of various configurations. In addition, the wafer transfer device 20 is configured to be capable of transferring the combined wafer T to/from the cassette C on the cassette placing table 10 and a transition device 30 to be described later.

In the carry-in/out station 2, the transition device 30 configured to deliver the combined wafer T to/from the processing station 3 is provided adjacent to the wafer transfer device 20 on the negative X-axis side of the wafer transfer device 20.

The processing station 3 is provided with, for example, three processing blocks B1 to B3. The first processing block B1, the second processing block B2, and the third processing block B3 are arranged in this order from the positive X-axis side (carry-in/out station 2 side) toward the negative X-axis side.

The first processing block B1 is equipped with an etching apparatus 40, a thickness measuring apparatus 41, and a wafer transfer device 50. The etching apparatus 40 and the thickness measuring apparatus 41 are stacked on top of each other. Here, the number and the layout of the etching apparatus 40 and the thickness measuring apparatus 41 are not limited to the shown example.

The etching apparatus 40 is configured to etch the rear surface Wb (ground surface) of the first wafer W after being subjected to grinding in a processing apparatus 80 to be described later, further thin the first wafer W (combined wafer T) after being subjected to the grinding, and smooth the ground surface by removing a grinding mark caused by the grinding processing. A detailed configuration of the etching apparatus 40 will be described later.

The thickness measuring apparatus 41 includes, as an example, a measurer (not shown) and a calculator (not shown). The measurer is provided with a sensor configured to measure the thickness of the first wafer W after being etched at multiple points. The calculator acquires a thickness distribution of the first wafer W from a measurement result (thickness of the first wafer W) obtained by the measurer, and also calculates flatness (TTV: Total Thickness Variation) of the first wafer W. Further, the calculation of the thickness distribution and the flatness of the first wafer W may be performed by a control device 90 to be described later instead of the calculator. In other words, the calculator (not shown) may be provided in the control device 90 to be described later. Additionally, the configuration of the thickness measuring apparatus 41 is not limited to the shown example, and various other configurations may be adopted.

The wafer transfer device 50 is disposed on the negative X-axis side of the transition device 30. The wafer transfer device 50 has, for example, two transfer arms 51 each configured to hold and transfer the combined wafer T. Each transfer arm 51 is configured to be movable in a horizontal direction and a vertical direction and pivotable around a horizontal axis and a vertical axis. The wafer transfer device 50 is configured to be capable of transferring the combined wafer T to/from the transition device 30, the etching apparatus 40, the thickness measuring apparatus 41, a cleaning apparatus 60 to be described later, a thickness measuring apparatus 61 to be described later, and a buffer apparatus 62 to be described later.

The second processing block B2 is provided with the cleaning apparatus 60, the thickness measuring apparatus 61, the buffer apparatus 62, and a wafer transfer device 70. The cleaning apparatus 60, the thickness measuring apparatus 61, and the buffer apparatus 62 are stacked on top of each other. Here, the number and the layout of the cleaning apparatus 60, the thickness measuring apparatus 61, and the buffer apparatus 62 are not limited to the shown example.

The cleaning apparatus 60 is configured to clean the rear surface Wb (ground surface) of the first wafer W after being subjected to the grinding in the processing apparatus 80 to be described later. For example, a brush is brought into contact with the rear surface Wb to scrub-clean the rear surface Wb. Further, a pressurized cleaning liquid may be used to clean the first wafer W. Additionally, the cleaning apparatus 60 may be configured to be capable of cleaning the rear surface Sb of the second wafer S concurrently when cleaning the first wafer W.

The thickness measuring apparatus 61 includes, as an example, a measurer (not shown) and a calculator (not shown). The measurer is provided with a sensor configured to measure the thickness of the first wafer W after being ground at multiple points. The calculator acquires a thickness distribution of the first wafer W from a measurement result (thickness of the first wafer W) obtained by the measurer, and also calculates flatness (TTV: Total Thickness Variation) of the first wafer W. Further, the calculation of the thickness distribution and the flatness of the first wafer W may be performed by the control device 90 to be described later instead of the calculator. In other words, the calculator (not shown) may be provided in the control device 90 to be described later. Additionally, the configuration of the thickness measuring apparatus 61 is not limited to the shown example, and various other configurations may be adopted.

The buffer apparatus 62 is configured to temporarily hold the combined wafer T before being processed which is transferred from the first processing block B1 to the second processing block B2. The configuration of the buffer apparatus 62 is not particularly limited. Further, the buffer apparatus 62 may include an alignment mechanism (not shown) configured to adjust a center position of the combined wafer T with respect to a chuck 83 to be described later, and/or a direction of the combined wafer T in a horizontal direction.

The wafer transfer device 70 is disposed on the positive Y-axis side of the cleaning apparatus 60, the thickness measuring apparatus 61, and the buffer apparatus 62, for example. The wafer transfer device 70 has, for example, two transfer arms 71 each configured to transfer the combined wafer T by attracting and holding the combined wafer T on a non-illustrated attracting/holding surface thereof. Each transfer arm 71 is supported by a multi-joint arm member 72, and is configured to be movable in a horizontal direction and a vertical direction and pivotable around a horizontal axis and a vertical axis. This wafer transfer device 70 is configured to be capable of transferring the combined wafer T to/from the etching apparatus 40, the thickness measuring apparatus 41, the cleaning apparatus 60, the thickness measuring apparatus 61, the buffer apparatus 62, and the processing apparatus 80 to be described later.

The third processing block B3 is equipped with the processing apparatus 80. The processing apparatus 80 is configured to grind the first wafer W to thin it, and functions as a thinning device in the present disclosure.

The processing apparatus 80 has a rotary table 81. The rotary table 81 is configured to be rotatable about a vertical rotation center line 82 by a rotating mechanism (not shown). Provided on the rotary table 81 are two chucks 83 each configured to attract and hold the combined wafer T. The chucks 83 are evenly arranged on the same circumference as the rotary table 81. The two chucks 83 are configured to be movable to a delivery position A0 and a processing position A1 as the rotary table 81 is rotated. Further, each of the two chucks 83 is configured to be rotatable around a vertical axis by a rotating mechanism (not shown).

A delivery of the combined wafer T is performed at the delivery position A0. A grinding device 84 is disposed at the processing position A1 to grind the first wafer W while attracting and holding the second wafer S with the chuck 83. The grinding device 84 has a grinder 85 equipped with a grinding whetstone (not shown) configured to be rotatable in an annular shape. Further, the grinder 85 is configured to be movable in a vertical direction along a supporting column 86.

Additionally, the configuration of the processing apparatus 80 is not limited to the shown example. By way of example, four chucks 83 may be provided on the rotary table 81, and these four chucks 83 may be configured to be movable between a delivery position of the combined wafer T, a rough grinder (not shown) configured to perform rough grinding of the first wafer W, an intermediate grinder (not shown) configured to perform intermediate grinding of the first wafer W, and a finishing grinder (not shown) configured to perform finishing grinding of the first wafer W. In addition, the processing apparatus 80 may be equipped with a thickness measurer (not shown) configured to measure the thickness of the first wafer W after being ground at multiple points.

The wafer processing system 1 described above is provided with the control device 90. The control device 90 is, for example, a computer equipped with a CPU, a memory, and the like, and has a program storage (not shown). The program storage stores therein a program for controlling the processing of the combined wafer T in the wafer processing system 1. The program may have been recorded on a computer-readable recording medium H, and may be installed from the recording medium H into the control device 90. Further, the recording medium H may be transitory or non-transitory.

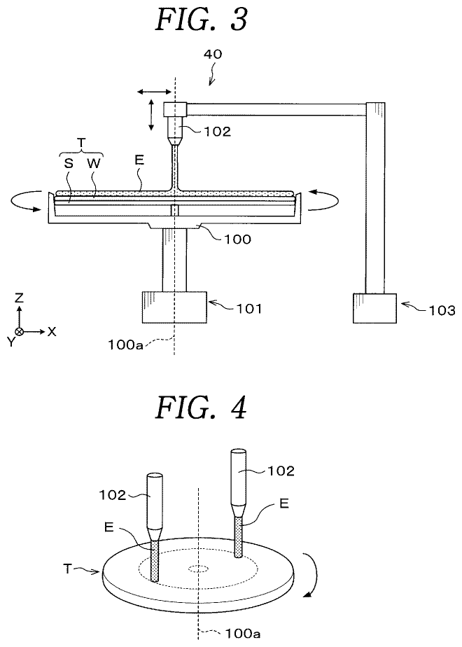

Now, the configuration of the etching apparatus 40 described above will be explained. As depicted in FIG. 3, the etching apparatus 40 includes a wafer holder 100 as a substrate holder, a rotating mechanism 101, and an etching liquid supply 102.

The wafer holder 100 is configured to hold an edge of the combined wafer T at multiple points, for example, three points in the present exemplary embodiment. Here, however, the configuration of the wafer holder 100 is not limited to the shown example. For instance, the wafer holder 100 may be provided with a chuck configured to attract and hold the combined wafer T from below. The rotating mechanism 101 is configured to rotate the combined wafer T (first wafer W) held by the wafer holder 100 about a vertical rotation center line 100a.

The etching liquid supply 102 has a nozzle configured to supply an etching liquid E to the rear surface Wb of the first wafer W held by the wafer holder 100. The etching liquid supply 102 is disposed above the wafer holder 100, and is configured to be movable in a horizontal direction and a vertical direction by a moving mechanism 103. As an example, the etching liquid supply 102 is configured to be capable of making reciprocating movements (scanning movements) while passing through the rotation center line 100a of the wafer holder 100, that is, through a space above a central portion of the first wafer W as shown in FIG. 4. In the following description, the reciprocating movement of the etching liquid supply 102 is assumed to be one loop.

The etching liquid E contains at least hydrofluoric acid, nitric acid, or mixed acid to properly etch the silicon of the first wafer W, which can be an etching target. Further, the etching liquid E may contain phosphoric acid or sulfuric acid. Additionally, the etching target is not limited to the first wafer W, and it may be, for example, amorphous silicon. Further, the etching target of the present exemplary embodiment is not limited to the rear surface Wb of the first wafer W. By way of example, the present exemplary embodiment is applicable even to a case of processing a wafer which is not processed by the processing apparatus 80. For example, if a film is formed on the rear surface Wb, this film can be an etching target.

The above-described etching apparatus 40 performs scan etching in which the etching liquid is supplied from the etching liquid supply 102 to the rear surface Wb of the first wafer W while rotating the first wafer W and reciprocating the etching liquid supply 102. In the present exemplary embodiment, an etching amount distribution in the scan etching is predicted by using a prediction model.

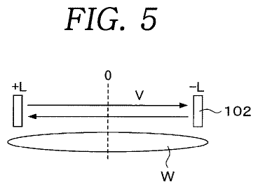

As shown in FIG. 5, the prediction model for the etching amount distribution is for scan etching that is performed under etching conditions of a constant scan speed and symmetrical scanning. That is, a scan speed V when reciprocating the etching liquid supply 102 is constant. In addition, a scan width L of the etching liquid supply 102 is left and right symmetrical from a center of the first wafer W, and the etching liquid supply 102 is reciprocated between one scan end “+L” and the other scan end “−L”. Hereinafter, this scan etching sequence may be referred to as “constant speed scan sequence,” and the derived prediction model may be referred to as “constant speed scan model”.

The constant speed scan model consists of the following equations (1) to (6).

$${ER}_{scan} ( R ) = {ER}_{ref} ( R ) \times {Ratio}_{scan} ( R ) \qquad ( 1 )$$

$${Ratio}_{scan} ( R ) = {b}_{0} \times exp ( {b}_{1} \times T + {b}_{2} ) + C \qquad ( 2 )$$

$${b}_{0} = f ( S , V ) \qquad ( 3 )$$

$${b}_{1} = f ( S , V ) \qquad ( 4 )$$

$${b}_{2} = f ( S , V ) \qquad ( 5 )$$

$$T = ( L - R ) / V \qquad ( 6 )$$

ER_{scan}: Etching amount when the etching liquid supply 102 is reciprocated
ER_{ref}: Etching amount when the etching liquid supply 102 is not reciprocated
Ratio_{scan}: Scan ratio
R: Position from the center of the first wafer W
T: Non-discharge time during which the etching liquid E is not supplied
C: Constant
S: Rotation speed when rotating the first wafer W
V: Scan speed when reciprocating the etching liquid supply 102
L: Scan width when reciprocating the etching liquid supply 102

The functions in the above-described equations (3) to (5) are determined by analyzing learning data. For example, etching of a constant speed scan sequence is performed on dummy wafers under a plurality of different etching conditions, and learning data regarding an etching amount distribution is acquired. Specifically, the etching of the dummy wafers is performed while varying a rotation speed S of the dummy wafer, the scan speed V for reciprocating the etching liquid supply 102, and the scan width L of the etching liquid supply 102. At this time, a processing time for the etching of each dummy wafer is the same.

The etching of the dummy wafer under each etching condition is performed for a predetermined required time. Then, the etching amount distribution of the dummy wafer is acquired, and the obtained etching amount distribution is outputted to the control device 90. The control device 90 compresses the received etching amount distribution under each etching condition into an etching amount distribution (etching rate) per unit time or unit loop, and stores each compressed etching amount distribution as learning data.

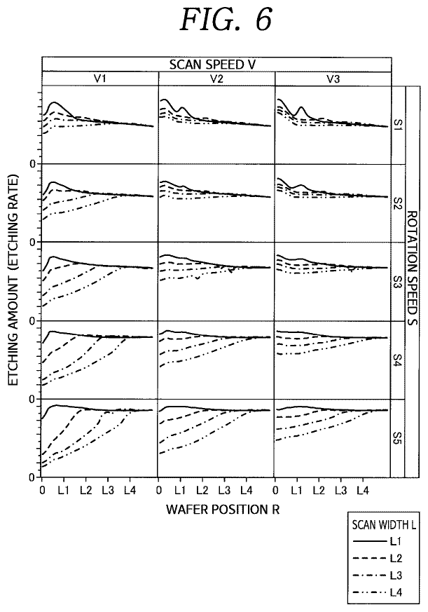

FIG. 6 presents an example of the acquired learning data. The rotation speed S of the dummy wafer is changed from S1 to S5. The scan speed V of the etching liquid supply 102 is changed from V1 to V3. The scan width L of the etching liquid supply 102 is changed from L1 to L4. In this way, the etching amount distribution is obtained for a plurality of, e.g., sixty types of etching conditions in the present exemplary embodiment. In a graph of each learning data, a horizontal axis represents a position in a diametrical direction ranging from a center (0 (zero) on the horizontal axis) of the dummy wafer to one outer edge, and a vertical axis represents an etching amount (etching rate).

In addition, although the above description has been provided for the example where the learning data is obtained by the etching of the dummy wafer, the etching target when acquiring the learning data is not limited to the dummy wafer. Specifically, an etching result of the first wafer W actually processed in the wafer processing system 1 may be stored as the learning data, for example. Additionally, when a film is formed on the rear surface Wb of the first wafer W, the film may be set as the etching target, and an etching result of the film may be stored as the learning data.

Now, a detailed method of deriving the above-described constant speed scan model will be explained.

First, the present inventors have investigated etching amount distributions in the scan etching, and have found out that an etching amount distribution in the case where the etching liquid supply 102 is fixed without being reciprocated (hereinafter, this case will sometimes be referred to as “no scanning”) works as a reference etching amount distribution for the etching amount distribution predicted by the constant speed scan model.

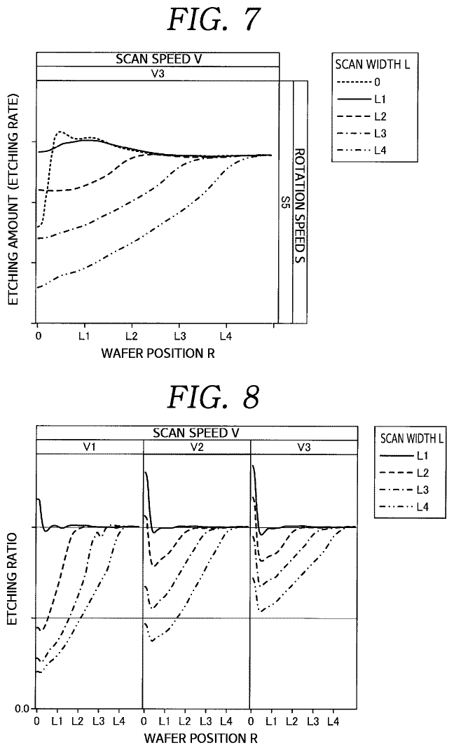

FIG. 7 shows etching amount distributions when the rotation speed S is S5, the scan speed V is V3, and the scan width L is varied from L1 to L4 in the learning data shown in FIG. 6. FIG. 7 also shows a reference etching amount distribution in the case of no scanning. Referring to FIG. 7, in the scan etching, only the etching amount distribution on the inner side of the scan width L changes, whereas the etching amount distribution on the outer side does not change. In other words, in the scan etching, only the etching amount distribution on the inner side of the scan width L changes from the reference etching amount distribution in the case of no scanning, whereas the etching amount distribution on the outer side of the scan width L exhibits the same behavior as the reference etching amount distribution. Therefore, the etching amount distribution in the case of no scanning can serve as a reference.

Next, the present inventors have separated variations in the etching amount distributions in the scan etching. Specifically, from the concept that the reference etching amount distribution in the case of no scanning exists, a ratio of the etching amount distribution of the scan etching to the reference etching amount distribution is defined as a scan ratio Ratio_{scan} by the following equation (7). By this scan ratio Ratio_{scan}, the effect of the scan etching can be quantitatively separated. FIG. 8 shows scan ratios Ratio_{scan} when the rotation speed S is set to S5, the scan speed V is varied from V1 to V3, and the scan width Lis varied from L1 to L4. A horizontal axis of FIG. 8 represents a position ranging from the center (0 (zero) on the horizontal axis) of the first wafer W to one outer end thereof in the diametrical direction, and a vertical axis represents a scan ratio Ratio_{scan}. Referring to FIG. 8, the scan ratio Ratio_{scan} on the inner side of the scan width L on the inner side of the scan width L changes, so the variation in the etching amount distribution in the scan etching can be investigated by being quantitatively separated. From the equation (7) below, the equation (1) in the constant speed scan model is derived as follows.

$${Ratio}_{scan} ( R ) = {b}_{0} \times exp ( {b}_{1} \times T + {b}_{2} ) + C \qquad ( 7 )$$

$${ER}_{scan} ( R ) = {ER}_{ref} ( R ) \times {Ratio}_{scan} ( R ) \qquad ( 1 )$$

Ratio_{scan}: Scan ratio
ER_{scan}: Etching amount when the etching liquid supply 102 is reciprocated
ER_{ref}: Etching amount when the etching liquid supply 102 is not reciprocated

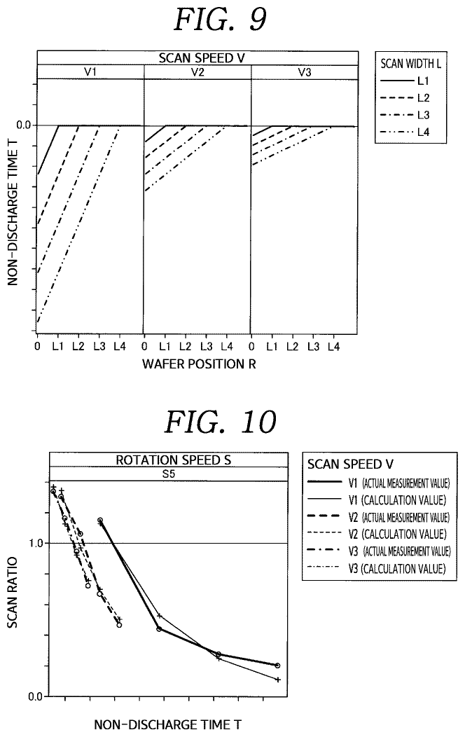

Additionally, the non-discharge time T is defined by the following equation (6). The non-discharge time T is the time during which the etching liquid E is not supplied to an inner side than the etching liquid supply 102 as a result of the etching liquid supply 102 being moved. In this non-discharge time T, an etching amount decreases. FIG. 9 shows non-discharge times T when the rotation speed S is set to S5, the scan speed V is varied from V1 to V3, and the scan width L is varied from L1 to L4. A horizontal axis of FIG. 9 represents a position ranging from the center (0 (zero) on the horizontal axis) of the first wafer W to one outer end thereof in the diametrical direction, and a vertical axis represents a non-discharge time T. As can be seen from FIG. 9, the non-discharge time T on the inner side of the scan width L on the inner side of the scan width L varies.

$$T = ( L - R ) / V \qquad ( 6 )$$

T: Non-discharge time during which the etching liquid E is not supplied
V: Scan speed when the etching liquid supply 102 is reciprocated
L: Scan width when the etching liquid supply 102 is reciprocated

Then, the present inventors have investigated a relationship between the scan ratio Ratio_{scan} and the non-discharge time T. FIG. 10 shows the relationship between the scan ratio Ratio_{scan} and the non-discharge time T when the rotation speed S is set to S5 and the scan speed V is varied from V1 to V3. A horizontal axis of FIG. 10 represents a non-discharge time T, and a vertical axis represents a scan ratio Ratio_{scan}. Referring to FIG. 10, the scan ratio Ratio_{scan} decreases exponentially with respect to the non-discharge time T, and can be defined by an attenuation curve model of the following equation (2). This attenuation curve model is also suitable for explaining a behavior of an actual physical phenomenon that the etching amount decreases with the increase of the time during which the etching liquid E is not supplied.

$${Ratio}_{scan} ( R ) = {b}_{0} \times exp ( {b}_{1} \times T + {b}_{2} ) + C \qquad ( 2 )$$

b₀: Scale (intercept)
b₁: Attenuation rate (slope)
b₂: Attenuation delay value
C: Asymptote

Here, b₀ denotes a scale (intercept) of an attenuation curve, and b₁ denotes an attenuation rate (inclination) of the attenuation curve. Further, b₂ represents an attenuation delay value of the attenuation curve. For example, b₂ is a correction term used when the amount of the etching liquid E is large with a large remaining amount on the first wafer W, and its effect, such as attenuation does not occur immediately, is large. C is an asymptote of the attenuation curve. For example, if C is not present, the scan ratio Ratio_{scan} approaches 0 (zero) in a mathematical sense. Actually, however, once the etching liquid E is supplied, the first wafer W is always etched, so the scan ratio Ratio_{scan} never becomes 0 (zero). C is a correction term to correct this phenomenon. For example, C can be determined by the equation (2) above while setting C=0 if C<0 and leaving C if C>0.

Additionally, when b₂ and C are determined to be practically unnecessary, they can be omitted by setting b₂=0 and C=0.

In addition, the scale b₀, the attenuation rate b₁, and the attenuation delay value b₂ depend on the rotation speed S and the scan speed V, and can be defined by the following equations (3) to (5), respectively.

$${b}_{0} = f ( S , V ) \qquad ( 3 )$$

$${b}_{1} = f ( S , V ) \qquad ( 4 )$$

$${b}_{2} = f ( S , V ) \qquad ( 5 )$$

S: Rotation speed when the first wafer W is rotated
V: Scan speed when the etching liquid supply 102 is reciprocated

Here, in FIG. 10, a bold line represents an actual measurement value obtained through an experiment, and a fine line indicates a calculation value obtained by the above equation (2) of the constant speed scan model. The actual measurement values and the calculation values are found to be roughly coincident, which mentions that the attenuation curve model of the equation (2) above is appropriate.

From the above, the constant speed scan model (prediction model for etching amount distribution) consisting of the following equations (1) to (6) is derived.

$${ER}_{scan} ( R ) = {ER}_{ref} ( R ) \times {Ratio}_{scan} ( R ) \qquad ( 1 )$$

$${Ratio}_{scan} ( R ) = {b}_{0} \times exp ( {b}_{1} \times T + {b}_{2} ) + C \qquad ( 2 )$$

$${b}_{0} = f ( S , V ) \qquad ( 3 )$$

$${b}_{1} = f ( S , V ) \qquad ( 4 )$$

$${b}_{2} = f ( S , V ) \qquad ( 5 )$$

$$T = ( L - R ) / V \qquad ( 6 )$$

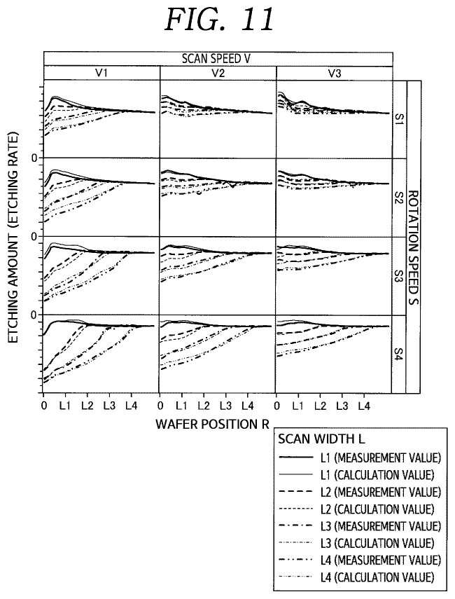

FIG. 11 is a graph which provides comparison of the actual measurement values (indicated by the bold line in FIG. 11) of the etching amount distribution obtained through the experiment and the calculation values (indicated by the fine line of FIG. 11) of the etching amount distribution calculated from the constant speed scan model. The rotation speed S is varied from S1 to S4, the scan speed V is varied from V1 to V3, and the scan width L is varied from L1 to L4. The actual measurement values and the calculation values are found to be roughly coincident, which mentions that the constant speed scan model of the equations (1) to (6) above is appropriate.

Now, a wafer processing performed by using the wafer processing system 1 configured as above will be described. In the present exemplary embodiment, the combined wafer T is previously formed in a bonding apparatus (not shown) outside the wafer processing system 1. Further, a peripheral portion of the first wafer W ranging from, for example, 0.5 mm to 3 mm from an outer end of the first wafer W in the diametrical direction may be removed in advance.

First, the cassette C accommodating therein a plurality of combined wafers T is placed on the cassette placing table 10 of the carry-in/out station 2. Then, the combined wafer T in the cassette C is taken out by the wafer transfer device 20 and transferred to the transition device 30. The combined wafer T transferred to the transition device 30 is then transferred to the buffer apparatus 62 by the wafer transfer device 50. In the buffer apparatus 62, the center position of the combined wafer T with respect to the chuck 83 and/or the direction of the combined wafer T in the horizontal direction may be adjusted.

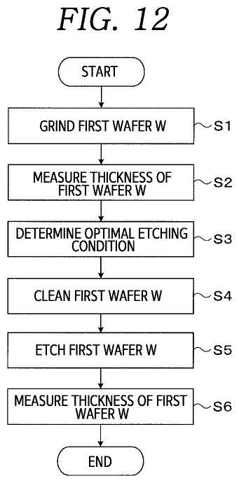

Subsequently, the combined wafer T is transferred to the processing apparatus 80 by the wafer transfer device 70, and delivered to the chuck 83 at the delivery position A0. The rear surface Sb of the second wafer S is attracted to and held by the chuck 83. Next, the chuck 83 is moved to the processing position A1, and the rear surface Wb of the first wafer W is ground by the grinding device 84. By this grinding processing, the thickness of the first wafer W (combined wafer T) is reduced to a required grinding target thickness (process S1 in FIG. 12).

Next, the combined wafer T is transferred to the thickness measuring apparatus 61 by the wafer transfer device 70. In the thickness measuring apparatus 61, the thickness of the first wafer W (combined wafer T) after being ground is measured at multiple points to obtain a thickness distribution of the first wafer W after being ground, and, also, flatness of the first wafer W is calculated (process S2 in FIG. 12). The thickness distribution and the flatness of the first wafer W thus calculated are outputted to, for example, the control device 90. When the processing apparatus 80 is provided with a thickness measuring device, the thickness of the first wafer W after being ground may be measured by the thickness measuring device of the processing apparatus 80.

The control device 90 determines an optimal etching condition for a subsequent etching processing from the received thickness distribution and flatness of the first wafer W (process S3 in FIG. 12). A detailed method of determining the optimal etching condition in the control device 90 will be described later.

The combined wafer T in which the thickness of the first wafer W has been measured is then transferred to the cleaning apparatus 60 by the wafer transfer device 70 or the wafer transfer device 50. In the cleaning apparatus 60, the rear surface Wb, which is the ground surface of the first wafer W after being ground, is cleaned (process S4 in FIG. 12). Additionally, in the cleaning apparatus 60, the rear surface Sb of the second wafer S may be cleaned as stated above. In addition, when measuring the thickness after the grinding in the thickness measuring apparatus 61 as in the present exemplary embodiment, the order of the processes S2, S3, and the process S4 may be reversed. That is, after cleaning the rear surface Wb of the first wafer W in the cleaning apparatus 60, the thickness of the first wafer W may be measured in the thickness measuring apparatus 61 to determine the optimal etching condition for an etching processing.

Next, the combined wafer T is transferred to the etching apparatus 40 by the wafer transfer device 50. In the etching apparatus 40, the rear surface Wb, which is the ground surface of the first wafer W, is etched by the etching liquid E under the optimal etching condition (process S5 in FIG. 12).

In the etching of the first wafer W, the wafer holder 100 (the first wafer W) is first rotated about the vertical rotation center line 100a, and the supply (discharge) of the etching liquid E from the etching liquid supply 102 is begun to start the etching of the rear surface Wb.

Further, in the etching of the first wafer W, while carrying on the supply of the etching liquid E from the etching liquid supply 102, the etching liquid supply 102 is reciprocated (scanned) so as to pass through the position above the rotation center of the first wafer W, that is, the rotation center line 100a, with the rotation center line 100a as a midpoint, as shown in FIG. 4. A detailed method for determining etching conditions, such as a rotation speed of the first wafer W, a scan speed when reciprocating the etching liquid supply 102, a scan width of the etching liquid supply 102, and so forth will be described later.

Once a required etching amount of the first wafer W is obtained, the supply of the etching liquid E from the etching liquid supply 102 is stopped, and the rear surface Wb of the first wafer W is rinsed with pure water, and is then dried by being shaken. Thereafter, the rotation of the wafer holder 100 (the first wafer W) is stopped, and the etching of the first wafer W is ended.

Here, the optimal etching condition for the first wafer W is determined based on the thickness distribution and the flatness of the first wafer W after being ground as described above. Specifically, the optical etching condition is determined based on a difference between the actual measurement values of the thickness distribution and the flatness of the first wafer W in the thickness measuring apparatus 61 and a thickness distribution and a flatness in a target surface shape (hereinafter, referred to as “target shape”) of the first wafer W after being etched. Then, in the process S5, the first wafer W is etched under the optimal etching condition, so that the difference between the actual measurement values and the target values of the thickness of the first wafer W is removed by the etching, and the first wafer W is processed into the target shape. Therefore, according to the present exemplary embodiment, the target surface shape of the first wafer W can be obtained appropriately, regardless of the surface shape of the first wafer W after being ground.

Next, the combined wafer T is transferred to the thickness measuring apparatus 41 by the wafer transfer device 50. In the thickness measuring apparatus 41, the thickness of the first wafer W (combined wafer T) after being etched is measured at multiple points to acquire a thickness distribution of the first wafer W after being etched, and, further, flatness of the first wafer W is also calculated (process S6 in FIG. 12). The calculated thickness distribution and flatness of the first wafer W are outputted to, for example, the control device 90 to be used to process another combined wafer T to be processed next in the wafer processing system 1, for example. Furthermore, in the case where the thickness of the first wafer W after being ground is measured in the thickness measuring device of the processing apparatus 80, the thickness of the first wafer W after being etched may be measured in the thickness measuring apparatus 61.

Afterwards, the combined wafer T after being subjected to all the required processes is transferred to the cassette C of the cassette placing table 10 via the transition device 30. In this way, the series of processes of the wafer processing in the wafer processing system 1 are completed.

Now, the detailed method of determining the aforementioned optimal etching condition (process S3 in FIG. 12) will be discussed.

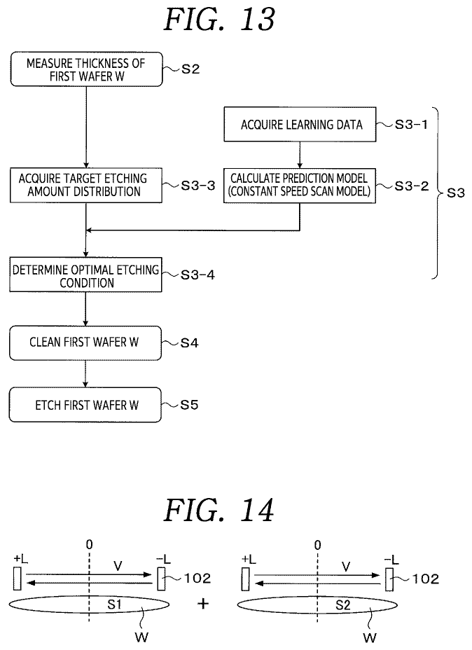

First, in determining the optimal etching conditions, learning data is acquired prior to the processing of the combined wafer T in the wafer processing system 1 (process S3-1 in FIG. 13). A prediction model for etching amount distribution is derived from the learning data (process S3-2 in FIG. 13).

In the process S3-1, etching of a constant speed scan sequence is performed on a dummy wafer to acquire the learning data upon the etching amount distribution shown in FIG. 6, as described above.

In the process S3-2, the prediction model for etching amount distribution consisting of the following equations (1) to (6), that is, a constant speed scan model, is derived. At this time, the function in each of the following equations (3) to (5) is determined by analyzing the learning data acquired in the process S3-1.

$${ER}_{scan} ( R ) = {ER}_{ref} ( R ) \times {Ratio}_{scan} ( R ) \qquad ( 1 )$$

$${Ratio}_{scan} ( R ) = {b}_{0} \times exp ( {b}_{1} \times T + {b}_{2} ) + C \qquad ( 2 )$$

$${b}_{0} = f ( S , V ) \qquad ( 3 )$$

$${b}_{1} = f ( S , V ) \qquad ( 4 )$$

$${b}_{2} = f ( S , V ) \qquad ( 5 )$$

$$T = ( L - R ) / V \qquad ( 6 )$$

ER_{scan}: Etching amount when the etching liquid supply 102 is reciprocated
ER_{ref}: Etching amount when the etching liquid supply 102 is not reciprocated
Ratio_{scan}: Scan ratio
R: Position from the center of the first wafer W
T: Non-discharge time during which the etching liquid E is not supplied
C: Constant
S: Rotation speed when the first wafer W is rotated
V: Scan speed when the etching liquid supply 102 is reciprocated
L: Scan width when the etching liquid supply 102 is reciprocated

In parallel with the processes S3-1 and S3-2, a target etching amount distribution in the etching processing of the process S5 is acquired (process S3-3 in FIG. 13). The target etching amount distribution is acquired based on a thickness distribution (hereinafter, referred to as “target thickness distribution”) in a target shape of the first wafer W after being etched and a thickness distribution (hereinafter referred to as “actual thickness distribution”) in a surface shape of the first wafer W after being ground, which is acquired in the process S2. As an example, the target etching amount distribution can be obtained by calculating a difference between the target thickness distribution and the actual thickness distribution of the first wafer W.

Next, etching conditions allowing the etching amount distribution calculated by using the constant speed scan model in the process S3-2 to approximate the target etching amount distribution obtained in the process S3-3 are determined. Although a method of determining these etching conditions is not particularly limited, optimization calculation such as the least square method, for example, may be employed. Then, these etching conditions are determined as optimal etching conditions (process S3-4 in FIG. 13). In addition, the optimal etching conditions determined in the process S3-4 correspond to a prediction target etching condition in the present disclosure.

Thereafter, the rear surface Wb of the first wafer W is cleaned in the process S4, and then, the rear surface Wb of the first wafer W is etched under the optimal etching condition in the process S5. That is, in the etching apparatus 40, the combined wafer T (first wafer W) is rotated at a rotation speed determined according to the optimal etching condition, and the etching liquid E is supplied to the first wafer W while moving the etching liquid supply 102 at a scan speed and a scan width determined according to the optimal etching condition.

Determination of the optimal etching condition and the etching processing on the first wafer W based on the optimal etching condition are performed as described above.

According to the above-described exemplary embodiment, the etching amount distribution can be appropriately predicted by using the constant speed scan model consisting of the above-specified equations (1) to (6). Thus, in controlling the etching amount distribution, the working time required for the control can be suppressed without relying on the ability of the engineer as in the conventional cases, so that the completeness of the control can be improved. In addition, it is possible to suppress the variations in the number of processes involved in determining the optimal etching conditions in the process S3, so that the accuracy of the optimal etching conditions can be improved.

Furthermore, in the process S5, the first wafer W can be etched under the optimal etching conditions determined in the process S3. Therefore, the etching amount distribution in the etching processing can be brought closer to the target etching amount distribution, and, as a result, the surface shape of the first wafer W after being etched can be set to the target shape. In other words, the optimal etching conditions can be determined from arbitrary etching conditions, and the surface shape of the first wafer W after being etched can be appropriately controlled.

The present inventors have actually performed simulations and found out that non-uniformity of the thickness distribution of the first wafer W after being etched can be set within an allowable range regardless of whether the target etching amount distribution has a V-shape, an A-shape, an M-shape, or a W-shape. In addition, the flatness (TTV) of the first wafer W after being etched has been found to be improved as compared to conventional cases. Here, the V-shape is a distribution in which the etching amount at the center of the first wafer W is smaller than etching amounts at both ends thereof, and this distribution has an approximately V-shape in a graph where a horizontal axis represents a wafer position and a vertical axis represents an etching amount. The A-shape is a distribution in which the etching amount at the center of the first wafer W is larger than the etching amounts at both ends thereof, and this distribution has an approximately A-shape, which is vertically opposite to the V-shape, in the above graph. The M-shape is a shape in which two A-shapes are arranged with the center of the first wafer W therebetween in the above graph, and is a distribution having an approximately M-shape as a whole. The W-shape is a shape in which two V-shapes are arranged with the center of the first wafer W therebetween in the above graph, and is a distribution having an approximately W-shape as a whole.

Moreover, since the processes S1 to S6 are performed on every single sheet of combined wafer T, the surface shape of the first wafer W after being etched can be controlled to the target shape even if the surface shape of each sheet of first wafer W before being etched (after being ground in the present exemplary embodiment) is different.

Although the above exemplary embodiment has been described for the case where the prediction model for the etching amount distribution is the constant speed scan model, it is also possible to predict an etching amount distribution of scan etching performed in another scan sequence.

For example, another scan sequence to which the present disclosure is applied may be a sequence in which constant speed scan sequences with a plurality of etching conditions are connected. Hereinafter, this scan sequence will sometimes be referred to as “multiple connection sequence,” and a prediction model for an etching amount distribution in the multiple connection sequence will sometimes be referred to as “multiple connection scan model.”

As shown in FIG. 14, a constant speed scan sequence 1 and a constant speed scan sequence 2 are connected to produce a multiple connection sequence. Additionally, in FIG. 14, the connection between the left drawing (constant speed scan sequence 1) and the right drawing (constant speed scan sequence 2) is indicated by ‘+’. In this example, in the constant speed scan sequence 1 and the constant speed scan sequence 2, the rotation speed S of the first wafer W is set to be different to S1 and S2, respectively. The multiple connection scan model is derived by adding the constant speed scan model 1 and the constant speed scan model 2 to each other according to a time ratio of the constant speed scan sequence 1 and the constant speed scan sequence 2. Here, the time ratio may be a ratio of the number of loops.

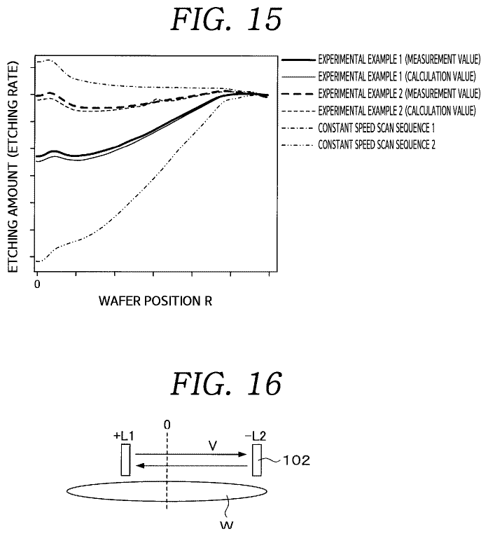

FIG. 15 is a graph showing etching amount distributions in the respective cases where the first wafer W is etched in the constant speed scan sequence 1, the constant speed scan sequence 2, and the multiple connection sequence. A horizontal axis of FIG. 15 represents a position ranging from the center (0 (zero) on the horizontal axis) of the first wafer W to one outer end in the diametrical direction, and a vertical axis represents an etching amount (etching rate).

In FIG. 15, an actual measurement value of the etching amount distribution in the case of performing the etching in the constant speed scan sequence 1 is indicated by a dashed dotted line. Further, an actual measurement value of the etching amount distribution in the case of performing the etching in the constant speed scan sequence 2 is indicated by a dashed double-dotted line.

In contrast, Experimental example 1 (bold solid line) shows an actual measurement value of an etching amount distribution when the constant speed scan sequence 1 and the constant speed scan sequence 2 are performed at a time (number of loops) ratio of 1:1. A fine solid line indicates a calculation value of the etching amount distribution under the etching conditions of Experimental example 1. This calculation value is the sum of ½ of the etching amount distribution of the constant speed scan model 1 and ½ of the etching amount distribution of constant speed scan model 2.

Experimental example 2 (bold dashed line) shows an etching amount distribution when the constant speed scan sequence 1 and the constant speed scan sequence 2 are performed at a time ratio of 5:1. A fine dashed line indicates a calculation value of the etching amount distribution under the etching conditions of Experimental example 2. This calculation value is the sum of ⅚ of the etching amount distribution of the constant speed scan model 1 and ⅙ of the etching amount distribution of the constant speed scan model 2.

In this case, in any of Experimental examples 1 and 2, the actual measurement value and the calculation value roughly coincide. Therefore, in the multiple connection scan model, the etching amount distribution can be appropriately predicted. Further, in comparison of Experimental example 1 and Experimental example 2, the etching amount at the center of the wafer is less than the etching amount at the outer periphery thereof in Experimental example 1, whereas the etching amount distribution is uniform within the surface of the wafer in Experimental example 2. In other words, by adjusting the time ratio, the required etching amount distribution can be obtained, and, as a result, the surface shape of the wafer after being etched can be controlled.

Furthermore, in the above-described example, the constant speed scan sequences 1 and 2 with the different rotation speeds S of the first wafer W as the etching condition are connected. However, it may be possible to connect constant speed scan sequences which are different in another etching condition, such as the scan speed V, the scan width L, etc. of the etching liquid supply 102.

For example, another scan sequence to which the present disclosure is applied may be a sequence in which the scan width L of the etching liquid supply 102 is asymmetric from the center of the first wafer W. Hereinafter, this scan sequence will sometimes be referred to as “asymmetric scan sequence”, and a prediction model for an etching amount distribution in the asymmetric scan sequence will sometimes be referred to as “asymmetric scan model.”

As shown in FIG. 16, in the asymmetric scan sequence, the scan width L from the center of the first wafer W to one scan end is L1, and the scan width L from the center of the first wafer W to the other scan end is L2. In this case, the asymmetric scan model is derived by adding a constant speed scan model 1 and a constant speed scan model 2 according to a time ratio (ratio of number of loops) of the constant speed scan sequence 1 in which the scan width L is set to L1 and the constant speed scan sequence 2 in which the scan width L is set to L2.

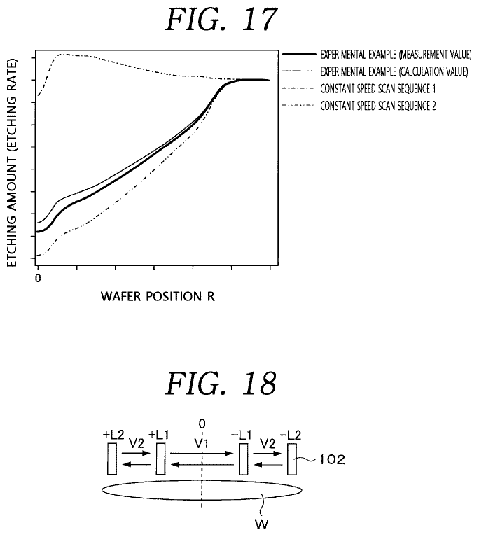

FIG. 17 is a graph showing etching amount distributions in the respective cases where the first wafer W is etched in the constant speed scan sequence 1, the constant speed scan sequence 2, and the asymmetric scan sequence. A horizontal axis of FIG. 17 represents a position in the diametrical direction ranging from the center (0 (zero) on the horizontal axis) of the first wafer W to one outer end thereof, and a vertical axis represents an etching amount (etching rate).

In FIG. 17, an actual measurement value of the etching amount distribution in the case of performing the etching in the constant speed scan sequence 1 is indicated by a dashed dotted line. Further, an actual measurement value of the etching amount distribution in the case of performing the etching in the constant speed scan sequence 2 is indicated by a dashed double-dotted line.

Meanwhile, Experimental example (bold solid line) shows an actual measurement value of an etching amount distribution when the constant speed scan sequence 1 and the constant speed scan sequence 2 are performed at a time (number of loops) ratio of 1:4. A fine solid line indicates a calculation value of the etching amount distribution under the etching conditions of Experimental example. This calculation value is the sum of ⅕ of the etching amount distribution of the constant speed scan model 1 and ⅘ of the etching amount distribution of constant speed scan model 2.

In this case, in Experimental example as well, the actual measurement value and the calculation value roughly coincide. Therefore, in the asymmetric scan model, the etching amount distribution can be appropriately predicted. As a result, the etching amount distribution can be appropriately controlled, which enables the controls of the surface shape of the wafer after being etched.

In addition, when the asymmetric scan model is used, the processing time of the scan sequence can be reduced. For example, assume that the time required for one loop in the constant speed scan sequence 1 is 10 seconds and the time required for one loop in the constant speed scan sequence 2 is 20 seconds, it takes 30 seconds to predict the etching amount distribution in the asymmetric scan sequence. In contrast, when the asymmetric scan model is used, 0.5 loop of the constant speed scan sequence 1 and 0.5 loop of the constant speed scan sequence 2 can be combined, so the time required to predict the etching amount distribution can be shortened to 15 seconds (half).

As another example, another scan sequence to which the present disclosure is applied may be a sequence in which the scan speed V of the etching liquid supply 102 changes in the diametrical direction of the first wafer W. That is, when the etching liquid supply 102 is moved from the center of the first wafer W to the scan end, the scan speed V changes at a shifting point in the diametrical direction of the first wafer W. Hereinafter, this scan sequence will sometimes be referred to as “variable speed scan sequence,” and a prediction model for an etching amount distribution in the variable speed scan sequence will sometimes be referred to as “variable speed scan model.”

As shown in FIG. 18, in the variable speed scan sequence, the scan speed V is set to a first scan speed V1 in the range from the center of the first wafer W to a scan width L1 (shifting point), and the scan speed V is set to a second scan speed V2 in the range from the scan width L1 to a scan width L2 (scan end). In this case, the variable speed scan model is derived by combining a constant speed scan model 1 in which the scan speed V is set to V1 and a constant speed scan model 2 in which the scan speed V is set to V2.

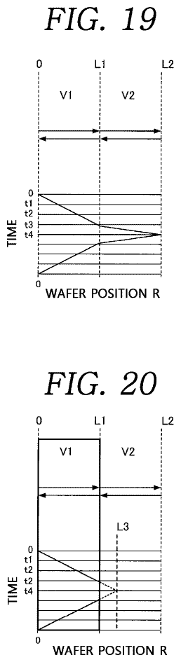

FIG. 19 is an explanatory diagram showing a change in the position of the etching liquid supply 102 over time in the variable speed scan sequence. A horizontal axis of FIG. 19 represents a position in the diametrical direction ranging from the center (0 (zero) on the horizontal axis) of the first wafer W to one outer end thereof, and a vertical axis represents an elapsed time.

In this case, as depicted in FIG. 20, the range from the center of the first wafer W to the scan width L1 in the variable speed scan sequence matches a constant speed scan sequence of a scan width L3. Therefore, in the variable speed scan model, in the range from the center of the first wafer W to the scan width L1, the constant speed scan model 1 with the etching conditions of the first scan speed V1 and the scan width L3 is applied.

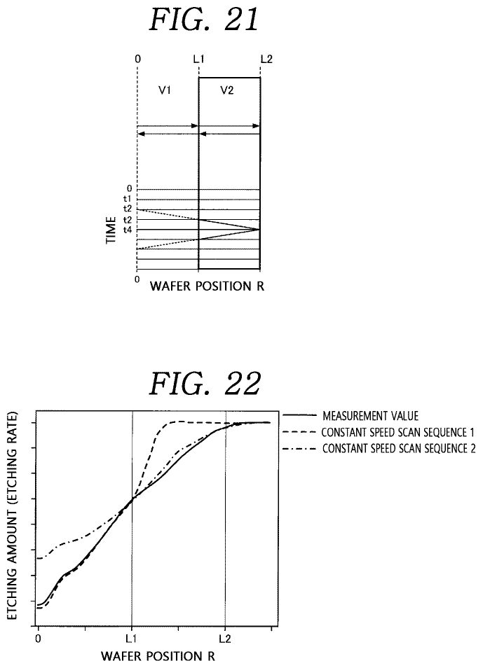

Furthermore, as shown in FIG. 21, the range from the scan width L1 to the scan width L2 in the variable speed scan sequence matches a half of the constant speed scan sequence of the scan width L2. Therefore, in the range from the scan width L1 to the scan width L2 in the variable speed scan model, the constant speed scan model 2 in which the etching amount distribution is the half of the constant speed scan sequence with the etching conditions of the second scan speed V2 and the scan width L2 is applied.

FIG. 22 is a graph showing an etching amount distribution in the case of etching the first wafer W in the variable speed scan sequence and etching amount distributions calculated by using the variable speed scan models (the constant speed scan model 1 and the constant speed scan model 2). A horizontal axis of FIG. 22 represents a position in the diametrical direction from the center (0 (zero) on the horizontal axis) of the first wafer W to one outer end, and a vertical axis represents an etching amount (etching rate).

In FIG. 22, a solid line represents an actual measurement value of the etching amount distribution when the first wafer W is etched in the variable speed scan sequence. A dashed line indicates the etching amount distribution calculated by using the constant speed scan model 1, and a dashed dotted line indicates the etching amount distribution calculated by using the constant speed scan model 2. In this case, in the range from the center of the first wafer W to the scan width L1, the actual measurement value and the calculated value of the constant speed scan model 1 are approximately same. Further, in the range from the scan width L1 to the scan width L2, the actual measurement value and the calculation value of the constant speed scan model 2 are approximately same. Therefore, in the variable speed scan model, by applying the constant speed scan model 1 in the range from the center of the first wafer W to the scan width L1 and applying the constant speed scan model 2 in the range from the scan width L1 to the scan width L2, the etching amount distribution can be appropriately predicted. As a result, the etching amount distribution can be appropriately controlled, and, thus, the surface shape of the wafer after being etched can be controlled.

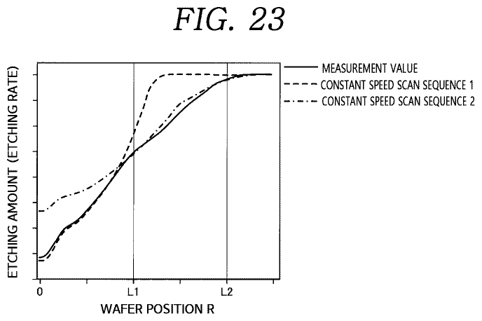

Moreover, as shown in FIG. 23, an intersection of the etching amount distribution of the constant speed scan model 1 and the etching amount distribution of the constant speed scan model 2 may deviate from the position of the scan width L1 (shifting point). In this case, the constant speed scan model 1 and the constant speed scan model 2 may be combined by using the intersection as a boundary.

Furthermore, a difference between the above-described intersection of the etching amount distribution of the constant speed scan model 1 and the etching amount distribution of the constant speed scan model 2 and the speed shifting point is caused by a sudden change in the etching amount due to a sudden change in the scan speed. Thus, the etching amount distribution of the constant speed scan model 1 or the constant speed scan model 2 may be corrected according to a difference between the first scan speed V1 and the second scan speed V2. By correcting the boundary condition in this way, the etching amount distribution can be predicted more appropriately.

In addition, the variable speed scan sequence is useful for making the etching amount distribution uniform within the surface of the wafer to thereby flatten the surface shape of the first wafer W. For example, when the etching liquid supply 102 is fixed (in the case of no scanning), the surface of the center of the first wafer W protrudes upwards as compared to the surface of the outer peripheral portion thereof. In the constant speed scan sequence, such protrusion of the surface of the center of the first wafer W can be suppressed. However, by performing the variable speed scan sequence, the surface shape of the first wafer W can be further flattened.

In the above-described exemplary embodiment, the constant speed scan model, the multiple connection scan model, the asymmetric scan model, and the variable speed scan model have been described individually. However, a prediction model can be produced by combining any or all of these scan models to predict an etching amount distribution. In such a case, the etching amount distribution can be controlled as required.

The above exemplary embodiment has been described for the example where various processings are performed on the rear surface Wb of the first wafer W in the combined wafer T in which the first wafer W and the second wafer S are bonded to each other. However, the processing target is not limited thereto. By way of example, a thinning processing or an etching processing may be performed on a single sheet of wafer alone. The processing target may be a film formed on the surface of the wafer, for example, an oxide film or titanium nitride. In this case, the etching liquid supply 102 in the etching apparatus 40 may be configured to switch the supply of different types of etching liquids E depending on the etching target. Further, when a film formed on the surface of a wafer is an etching target, for example, an etching result of the corresponding film may be stored as the parts. In the thickness measuring apparatus 61, the thickness of the film is measured. Additionally, when a protective tape is attached on a device surface of the wafer, a thinning processing or an etching processing may be performed on a surface of the wafer opposite to where the protective tape is provided. Furthermore, a thinning processing or an etching processing may be performed on the wafer cut out from an ingot with a wire saw or the like and lapped. The etching processing can be performed for any of the various processing targets under the optimal etching condition of the above-described exemplary embodiment.

Further, when a film is formed on the rear surface Wb of the first wafer, for example, this film may be an etching target. In this case, the thickness measuring apparatus 61 measures the thickness of the film, for example. That is, in the process S2, the thickness of the film is measured instead of the thickness of the first wafer W, and, further, a thickness distribution of the film and flatness of the film are measured. Then, in the process S3, the optimal etching condition is determined based on the calculated thickness distribution and flatness of the film.

In addition, although the wafer processing system 1 is equipped with the various apparatuses other than the etching apparatus 40, the apparatus configuration to which the present disclosure is applied is not limited thereto. By way of example, the processing apparatus 80, which is the thinning device, may be omitted. In this case, the etching target is not limited to the wafer after being subjected to the thinning processing. Further, the technique of the present disclosure can also be applied to a case of etching the wafer in an etching apparatus alone.

In the above-described exemplary embodiment, the first wafer W is thinned in the processing apparatus 80. However, the thinning method is not limited thereto. For example, the thinning processing of the first wafer W includes polishing of the rear surface Wb of the first wafer W as well. Alternatively, the first wafer W may be thinned by being separated starting from a modification layer (not shown) formed inside the first wafer W by a laser processing. In this case, the wafer processing system 1 is provided with, instead of the processing apparatus 80, a laser processing apparatus (not shown) configured to form the modification layer (not shown).

It should be noted that the above-described exemplary embodiment is illustrative in all aspects and is not anyway limiting. The above-described exemplary embodiment may be omitted, replaced and modified in various ways without departing from the scope and the spirit of claims.

### EXPLANATION OF CODES

1: Wafer processing system
40: Etching apparatus
90: Control device
100: Wafer holder
101: Rotating mechanism
102: Etching liquid supply
103: Moving mechanism
E: Etching liquid
T: Combined wafer
W: First wafer
S: Second wafer

1. A substrate processing method of processing a substrate, comprising:
etching a surface of an etching target on the substrate by supplying an etching liquid from an etching liquid supply to the surface, while rotating the etching target and reciprocating the etching liquid supply in a diametrical direction through a position above a rotation center of the etching target; and
predicting an etching amount distribution in the diametrical direction of the etching target when etching the surface of the etching target under prediction target etching conditions
wherein the predicting of the etching amount distribution comprises:
acquiring learning data including etching amount distribution when the surface of the etching target is etched under multiple different etching conditions; and
predicting the etching amount distribution under the prediction target etching conditions from following equations (1) to (6) by using the learning data:
$${ER}_{scan} ( R ) = {ER}_{ref} ( R ) \times {Ratio}_{scan} ( R ) \qquad ( 1 )$$
$${Ratio}_{scan} ( R ) = {b}_{0} \times exp ( {b}_{1} \times T + {b}_{2} ) + C \qquad ( 2 )$$
$${b}_{0} = f ( S , V ) \qquad ( 3 )$$
$${b}_{1} = f ( S , V ) \qquad ( 4 )$$
$${b}_{2} = f ( S , V ) \qquad ( 5 )$$
$$T = ( L - R ) / V \qquad ( 6 )$$
and
wherein, in the equations (1) to (6):
ER_{scan}: Etching amount when the etching liquid supply is reciprocated,
ER_{ref}: Etching amount when the etching liquid supply is not reciprocated,
Ratio_{scan}: Scan ratio,
R: Position from the center of the etching target,
T: Non-discharge time during which the etching liquid is not supplied,
C: Constant,
S: Rotation speed when rotating the etching target,
V: Scan speed when reciprocating the etching liquid supply, and
L: Scan width when reciprocating the etching liquid supply.

2. The substrate processing method of claim 1,
wherein functions in the respective equations (3) to (5) are determined by analyzing the learning data.

3. The substrate processing method of claim 1,
wherein the etching amount distribution is derived by adding the etching amount distributions predicted by the equations (1) to (6) under different prediction target etching conditions according to a time ratio of etching in the different prediction target etching conditions.

4. The substrate processing method of claim 1,
wherein when the etching liquid supply is reciprocated asymmetrically with respect to the rotation center of the etching target, the etching amount distribution is derived by adding the etching amount distributions predicted by the equations (1) to (6) under different scan widths according to a time ratio of etching at the different scan widths.

5. The substrate processing method of claim 1,
wherein when a scan speed changes at a shifting point in the diametrical direction of the etching target when the etching liquid supply is moved from the rotation center of the etching target to a scan end,
the etching amount distribution is derived by combining the etching amount distribution predicted by the equations (1) to (6) under a first scan speed from the rotation center to the shifting point and the etching amount distribution predicted by the equations (1) to (6) under a second scan speed from the shifting point to the scan end.

6. The substrate processing method of claim 5,
wherein at the shifting point, either the etching amount distribution predicted by the equations (1) to (6) under the first scan speed or the etching amount distribution predicted by the equations (1) to (6) under the second scan speed is corrected according to the first scan speed and the second scan speed.

7. The substrate processing method of claim 1, further comprising:
acquiring a thickness distribution in the diametrical direction of the etching target by measuring a thickness of the etching target before the etching of the surface of the etching target; and
predicting the etching amount distribution based on the acquired thickness distribution of the etching target.

8. A substrate processing system of processing a substrate, comprising:
a substrate holder configured to hold the substrate;
a rotating mechanism configured to rotate the substrate holder;
an etching liquid supply configured to supply an etching liquid from above a surface of an etching target on the substrate held by the substrate holder;
an etching apparatus equipped with a moving mechanism configured to move the etching liquid supply in a horizontal direction; and
a control device and a program storage including a program,
wherein the program storage and the program are configured, with the control device, to perform:
etching the surface of the etching target by supplying the etching liquid from the etching liquid supply to the surface of the etching target, while rotating the etching target and reciprocating the etching liquid supply in a diametrical direction through a position above a rotation center of the etching target; and
predicting an etching amount distribution in the diametrical direction of the etching target when etching the surface of the etching target under prediction target etching conditions, and
wherein the predicting of the etching amount distribution comprises:
acquiring learning data including etching amount distributions when the surface of the etching target is etched under multiple different etching conditions; and
predicting the etching amount distribution under the prediction target etching condition from following equations (1) to (6) by using the learning data:
$${ER}_{scan} ( R ) = {ER}_{ref} ( R ) \times {Ratio}_{scan} ( R ) \qquad ( 1 )$$
$${Ratio}_{scan} ( R ) = {b}_{0} \times exp ( {b}_{1} \times T + {b}_{2} ) + C \qquad ( 2 )$$
$${b}_{0} = f ( S , V ) \qquad ( 3 )$$
$${b}_{1} = f ( S , V ) \qquad ( 4 )$$
$${b}_{2} = f ( S , V ) \qquad ( 5 )$$
$$T = ( L - R ) / V \qquad ( 6 )$$
and
wherein, in the equations (1) to (6):
ER_{scan}: Etching amount when the etching liquid supply is reciprocated,
ER_{ref}: Etching amount when the etching liquid supply is not reciprocated,
Ratio_{scan}: Scan ratio,
R: Position from the center of the etching target,
T: Non-discharge time during which the etching liquid is not supplied,
C: Constant,
S: Rotation speed when rotating the etching target,
V: Scan speed when reciprocating the etching liquid supply, and
L: Scan width when reciprocating the etching liquid supply.

9. The substrate processing system of claim 8,
wherein the control device determines functions in the respective equations (3) to (5) by analyzing the learning data.

10. The substrate processing system of claim 8,
wherein the control device derives the etching amount distribution by adding the etching amount distributions predicted by the equations (1) to (6) under different prediction target etching conditions according to a time ratio of etching in the different prediction target etching conditions.

11. The substrate processing system of claim 8,
wherein when the etching liquid supply is reciprocated asymmetrically with respect to the rotation center of the etching target, the control device derives the etching amount distribution by adding the etching amount distributions predicted by the equations (1) to (6) under different scan widths according to a time ratio of etching at the different scan widths.

12. The substrate processing system of claim 8,
wherein when a scan speed changes at a shifting point in the diametrical direction of the etching target when the etching liquid supply is moved from the rotation center of the etching target to a scan end, the control device derives the etching amount distribution by combining the etching amount distribution predicted by the equations (1) to (6) under a first scan speed from the rotation center to the shifting point and the etching amount distribution predicted by the equations (1) to (6) under a second scan speed from the shifting point to the scan end.

13. The substrate processing system of claim 12,
wherein the control device corrects, at the shifting point, either the etching amount distribution predicted by the equations (1) to (6) under the first scan speed or the etching amount distribution predicted by the equations (1) to (6) under the second scan speed according to the first scan speed and the second scan speed.

14. The substrate processing system of claim 8, further comprising:
a thickness measuring device configured to measure a thickness of the etching target before being etched,
wherein the control device predicts the etching amount distribution based on a thickness distribution of the etching target acquired from the thickness of the etching target measured by the thickness measuring device.
